(19) United States
(12) Patent Application Publication
(10) Pub. No.: US 2026/0247883 A1
(43) Pub. Date: Aug. 20, 2026

(54) METHOD OF FORMING AMORPHOUS LAYER OF BORON NITRIDE AND METHOD OF FORMING AMORPHOUS MATERIAL LAYER

(71) Applicants: Samsung Electronics Co., Ltd., Suwon-si (KR); UIF (University Industry Foundation), Yonsei University, Seoul (KR)

(72) Inventors: Taehoon KIM, Suwon-si (KR); Hyungjun KIM, Seoul (KR); Minji KIM, Seoul (KR); Jaewon KIM, Suwon-si (KR); Inkyu SOHN, Seoul (KR); Changseok LEE, Suwon-si (KR); Woochang LEE, Suwon-si (KR); Jaehong LEE, Suwon-si (KR); Yoonhoo HA, Suwon-si (KR)

(73) Assignees: Samsung Electronics Co., Ltd., Suwon-si (KR); UIF (University Industry Foundation), Yonsei University, Seoul (KR)

(21) Appl. No.: 19/298,859

(22) Filed: Aug. 13, 2025

(30) Foreign Application Priority Data
Feb. 18, 2025 (KR) 10-2025-0020960

(51) Int. Cl. H01L 21/02; C23C 16/34; C23C 16/455

(52) U.S. Cl. CPC H10P 14/6532; C23C 16/342; C23C 16/4554; H10P 14/6339; H10P 14/6939

(57) ABSTRACT

A method of forming an amorphous layer of boron nitride may include placing a target substrate having a deposition surface in a reaction chamber, depositing a boron nitride layer on the target substrate by sequentially exposing the deposition surface to a boron-precursor and a nitrogen-precursor, plasma-treating the boron nitride layer, maintaining the boron nitride layer at a process pressure lower than a process pressure during the plasma-treating for a certain maintaining time after the plasma-treating, and repeating multiple times the depositing the boron nitride layer, the plasma-treating the boron nitride layer, and the maintaining the boron nitride layer.

### CROSS-REFERENCE TO RELATED APPLICATION

This application is based on and claims priority under 35 U.S.C. § 119 to Korean Patent Application No. 10-2025-0020960, filed on Feb. 18, 2025 in the Korean Intellectual Property Office, the disclosure of which is incorporated by reference herein in its entirety.

### BACKGROUND

### 1. Field

The disclosure relates to a method of forming an amorphous layer of boron nitride and/or a method of forming an amorphous material layer.

### 2. Description of the Related Art

As the integration of integrated circuits has increased significantly, a gap between conductor patterns has gradually decreased. Accordingly, a parasitic capacitance between conductor patterns also has increased, and thus, the performance of electronic devices may deteriorate. For example, the parasitic capacitance may delay signal transmission of semiconductor devices. To reduce the parasitic capacitance, a low-k or ultra-low-k amorphous material layer has been proposed as an insulating layer provided between the conductor patterns. A method of forming a thin film of a crystalline material having no low-k properties by a chemical vapor deposition (CVD) method, an atomic layer deposition (ALD) method, etc. has been disclosed.

### SUMMARY

Provided is a method of forming a low-k or ultra-low-k amorphous material layer/a low-k or ultra-low-k boron nitride layer.

Provided is a method of forming an amorphous material layer/a boron nitride layer by which higher step coverage may be realized.

Provided is a method of forming an amorphous material layer/a boron nitride layer, each having higher air stability.

Additional aspects will be set forth in part in the description which follows and, in part, will be apparent from the description, or may be learned by practice of the presented embodiments of the disclosure.

According to an example embodiment of the disclosure, a method of forming an amorphous layer of boron nitride may include placing a target substrate having a deposition surface in a reaction chamber, depositing a boron nitride layer on the target substrate by sequentially exposing the deposition surface to a boron-precursor and a nitrogen-precursor, plasma-treating the boron nitride layer, maintaining the boron nitride layer at a process pressure lower than a process pressure during the plasma-treating for a certain maintaining time after the plasma-treating, and repeating multiple times the depositing the boron nitride layer, the plasma-treating of the boron nitride layer, and the maintaining of the boron nitride layer.

In some embodiments, in the depositing of the boron nitride layer, a process temperature may range from 250° C. to 400° C.

In some embodiments, in the depositing of the boron nitride layer, a process pressure of a process for supplying the boron-precursor may range from 100 mTorr to 200 mTorr, and a process pressure of a process for supplying the nitrogen-precursor may range from 100 mTorr to 500 mTorr.

In some embodiments, in the plasma-treating of the boron nitride layer, a kinetic energy of ions may be 35 eV or less.

In some embodiments, in the plasma-treating of the boron nitride layer, a process pressure may range from 100 mTorr to 500 mTorr.

In some embodiments, in the plasma-treating of the boron nitride layer, at least one of the boron-precursor and the nitrogen-precursor may be supplied to the reaction chamber.

In some embodiments, the process pressure in the maintaining of the boron nitride layer may range from 1 mTorr to 100 mTorr.

In some embodiments, the certain maintaining time may range from 1 second to 60 seconds.

In some embodiments, the depositing of the boron nitride layer may be performed multiple times, followed by the plasma-treating of the boron nitride layer and the maintaining of the boron nitride layer.

In some embodiments, a density of the amorphous layer of boron nitride may range from 1.7 g/cm³ to 3.45 g/cm³.

In some embodiments, a dielectric constant of the amorphous layer of boron nitride may be 4 or less.

According to an example embodiment of the disclosure, a method of forming an amorphous material layer may include placing a target substrate having a deposition surface in a reaction chamber, depositing a thin film of a target material on the deposition surface by exposing the deposition surface to a precursor of the target material, plasma-treating the thin film of the target material, maintaining the thin film of the target material at a process pressure lower than a process pressure during the plasma-treating for a certain maintaining time after the plasma-treating, and repeating multiple times the depositing of the thin film of the target material, the plasma-treating of the thin film of the target material, and the maintaining of the thin film of the target material.

In some embodiments, in the depositing of the thin film of the target material, a process temperature may range from 250° C. to 400° C.

In some embodiments, in the plasma-treating of the thin film of the target material, kinetic energy of ions may be 35 eV or less.

In some embodiments, in the plasma-treating of the thin film of the target material, at least one of precursors of the target material may be supplied to the reaction chamber.

In some embodiments, the process pressure in the maintaining of the thin film of the target material may range from 1 mTorr to 100 mTorr.

In some embodiments, the maintaining time may range from 1 second to 60 seconds.

In some embodiments, the depositing of the thin film of the target material may be performed multiple times, followed by the plasma-treating of the thin film of the target material and the maintaining of the thin film of the target material.

In some embodiments, the target material may include C, Si, B, SiN, BN, Al₂O₃, HfO₂, SiO₂, ZrO₂, SiC, ZnTe, GeTe, SiTe, SiON, AlON, SiOC, TeSeOₓ, (Ti, Al)N, (Zr, Ti)N, or LaAlO₃.

In some embodiments, the target material may include a unitary material, a binary material, or a ternary material.

According to an example embodiment of the present disclosure, a method of manufacturing an electronic device may include forming a gate insulating layer and a gate electrode on a channel region of a substrate, the gate electrode on the gate insulating layer; forming a source region and a drain region in the substrate, the source region and the drain region at opposite sides of the channel region of the substrate; and forming an isolation layer on each sidewall of the gate electrode and the gate insulating layer. The isolation layer may be formed using a method of forming an amorphous material layer (e.g., amorphous boron nitride layer) according to example embodiments.

According to an example embodiment of the present disclosure, a method of manufacturing a memory device may include forming a transistor in a substrate, the transistor including a pair of source/drain regions spaced apart from each other in the substrate, a gate electrode buried in the substrate between the pair of source/drain regions, and an insulating layer between the gate electrode and the substrate and between the pair of source/drain regions; and forming a capacitor connected to one of the pair of source/drain regions. The insulating layer may be formed using a method of forming an amorphous material layer (e.g., amorphous boron nitride layer) according to example embodiments.

According to an example embodiment of the present disclosure, a method of manufacturing a field effect transistor may include forming channels spaced apart from each other over a region of a substrate between a source and a drain on the substrate, opposite ends the channels being connected to the source and the drain, respectively; forming spacers alternately arranged between the channels on end regions of the channels, the spacers including first spacers connected to the source and second spacers connected to the drain; and forming a gate alternately arranged between the channels over the substrate and a gate insulating layer between the gate and the channels. The gate and the gate insulating layer may be between the first spacers and the second spacers. The spacers may be formed using a method of forming an amorphous material layer (e.g., amorphous boron nitride layer) according to example embodiments.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart of a method of forming an amorphous material layer, according to an embodiment;

FIGS. 2 to 10 are diagrams showing a method of forming an amorphous material layer, according to an embodiment;

FIG. 11 is a graph showing a Raman spectrum of a boron nitride layer formed by a thermal atomic layer deposition (T-ALD) process;

FIG. 12 is a graph showing a Raman spectrum of a boron nitride layer formed by a method using an in-situ cyclic plasma treatment (ISCP) according to the present embodiment;

FIG. 13 is a graph showing an X-ray diffraction spectrum of a boron nitride layer formed by a method according to the present embodiment;

FIG. 14 is a graph showing an X-ray reflection spectrum of a boron nitride layer formed by the T-ALD process;

FIG. 15 is a graph showing an X-ray reflection spectrum of a boron nitride layer formed by a method using the ISCP according to the present embodiment;

FIG. 16 is a graph showing an air stability test result of a boron nitride layer formed by a T-ALD process and a boron nitride layer manufactured by a method using the ISCP according to the present embodiment;

FIG. 17 is a graph showing a result of measuring a thickness of a boron nitride layer formed by a method according to the present embodiment;

FIG. 18 is a flowchart of a method of forming an amorphous material layer, according to an embodiment;

FIG. 19 is a diagram showing an electronic device including an electric field effect transistor, according to an embodiment;

FIG. 20 is a diagram showing a memory device according to an embodiment; and

FIG. 21 is a schematic cross-sectional view of an electric field effect transistor according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, a method of forming an amorphous layer of boron nitride according to various embodiments is described in detail with reference to the accompanying drawings. Throughout the drawings, like reference numerals denote like elements, and sizes of components in the drawings may be exaggerated for convenience of explanation, and clarity. Terms such as “first” and “second” are used herein merely to describe a variety of constituent elements, but the constituent elements are not limited by the terms. Such terms are used only for the purpose of distinguishing one constituent element from another constituent element.

As used herein, the singular forms “a,” “an,” and “the” are intended to include the plural forms as well, unless the context clearly indicates otherwise. Furthermore, when a part may “include” a certain component, unless specified otherwise, it may not be construed to exclude another component but may be construed to further include other components. Furthermore, the size or thickness of each constituent element illustrated in the drawings may be exaggerated for clarity of explanation. Furthermore, when a material layer is described to exist on a substrate or another layer, the material layer may exist in direct contact with the substrate or the other layer or a third layer may be interposed therebetween. In the following embodiment, as a material forming each layer is an example, other materials may be used therefor.

A low-k or ultra-low-k amorphous material layer, for example, an amorphous layer of boron nitride, has been proposed as an insulating layer to reduce a response delay due to a parasitic capacitance between semiconductor devices and/or between conductor patterns in various integrated circuits including semiconductor devices. An atomic layer deposition (ALD) method is a representative method for forming thin films. The ALD method includes a thermal atomic layer deposition (T-ALD) method, a plasma enhanced atomic layer deposition (PE-ALD) method, and an atomic layer annealing (ALA) method. While the T-ALD method exhibits excellent step coverage, in general, the T-ALD method is applied to crystalline thin films that do not have low-k properties. For growth of a boron nitride layer by the T-ALD method, a process temperature of about 400° C. or more is necessary, and thus, the T-ALD method may be inappropriate for a semiconductor process that requires a process temperature of 400° C. or less. Furthermore, when a boron nitride layer is grown at a process temperature of 400° C. or less based on the T-ALD method, due to low thin film density or low air stability, it is difficult to implement a stable amorphous layer of boron nitride. In the case of PE-ALD, it is difficult to obtain a good step coverage because a target material does not reach deep into a trench of a deposition surface with a high aspect ratio due to collisions of radicals and/or plasma ions. The ALA method is a crystalline thin film growth method that induces crystallization of the target material through a thermal treatment using plasma. According to the ALA method, as a crystalline boron nitride layer with a dielectric constant of 5 or more is formed, the ALA method is not suitable as a method of growing an amorphous layer of boron nitride with low-k properties.

The disclosure provides a method of forming an amorphous material layer and a method of forming an amorphous layer of boron nitride, based on the T-ALD method, which may improve the density of a thin film while maintaining amorphous properties by in-situ cyclic plasma treatment (ISCP) and limit and/or prevent crystallization of a precursor by radicals and/or ions in the subsequent process by applying a periodic maintaining time.

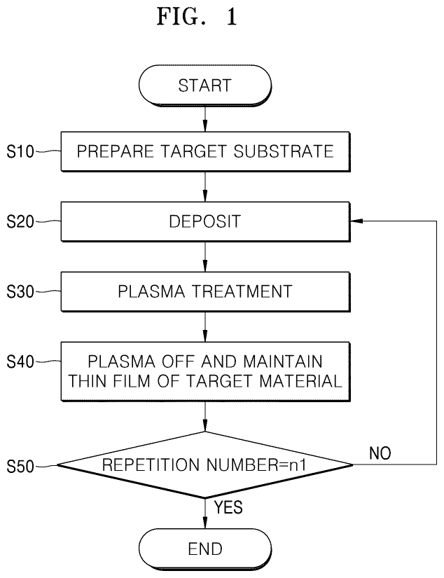

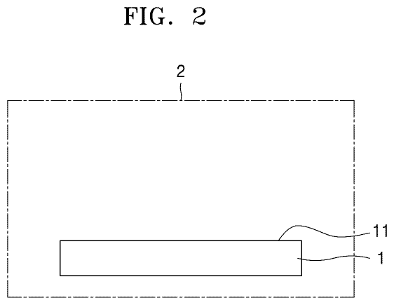

FIG. 1 is a flowchart of a method of forming an amorphous material layer, according to an embodiment. FIGS. 2 to 10 are diagrams showing a method of forming an amorphous material layer, according to an embodiment. Referring to FIG. 1, according to a method of forming an amorphous material layer according to an embodiment, an amorphous material layer of a target material is formed on a deposition surface 11 by performing a repeating process S50 of repeating, for example, ‘n1’ times, a deposition process S20, a plasma treatment process S30, and a maintaining process S40. The number of repetitions “n1” may be determined considering a target thickness of the amorphous material layer of the target material, for example, the amorphous layer of boron nitride.

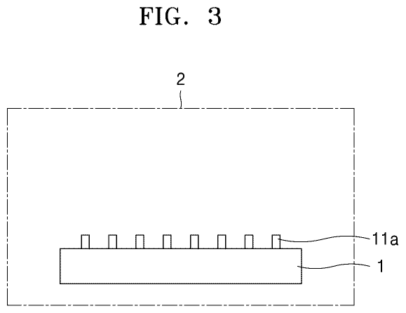

Referring to FIGS. 1 and 2, a target substrate 1 having the deposition surface 11 on which a thin film is to be formed is prepared (S10). For example, the target substrate 1 may include a silicon (Si) substrate or a sapphire substrate. The target substrate 1 may be an intermediate product having the deposition surface 11 in the semiconductor process. As illustrated in FIG. 2, the deposition surface 11 may be a flat surface. As illustrated in FIG. 3, a deposition surface 11a may be an uneven surface.

Before the target substrate 1 is placed within a reaction chamber 2, a pretreatment may be performed on the target substrate 1. For example, the pretreatment may include a cleaning process for the target substrate 1. For example, after the target substrate 1 is immersed in an organic solvent such as acetone and processed with ultrasound, the target substrate 1 may be cleaned with iso-propenyl alcohol (IPA) and a nitrogen gas. When the surface of the target substrate 1 is plasma-treated with oxygen hydrogen or NH₃, carbon (C) impurities remaining on the surface may be removed. Furthermore, the target substrate 1 may be immersed in an HF solution to remove the natural oxide, or the residual HF solution may be removed using anhydrous ethanol and N2 gas.

The target substrate 1 is placed within the reaction chamber 2, and the internal temperature of the reaction chamber 2 is controlled to a certain process temperature. The process temperature may be 400° C. or less. For example, the process temperature may be a specific temperature between 250° C. to 400° C. As the temperature of the deposition surface 11 increases, the deposition surface 11 may be activated.

Next, depositing the thin film of the target material on the deposition surface 11 by exposing the deposition surface 11 to a precursor of the target material, that is, the deposition process S20, is performed under a first process pressure. The deposition process may include exposing the deposition surface 11 to the precursor of the target material under the first process pressure, and a purging process of removing a residual gas after the exposing process. The target material may have various types. The target material may include one or more constituent elements. For example, the target material may include a unary material. The unary material may include, for example, C, Si, or boron (B). For example, the target material may include a binary material. The binary material may include, for example, SiN, BN, Al₂O₃, HfO₂, SiO₂, ZrO₂, SiC, ZnTe, GeTe, or SiTe. For example, the target material may include a ternary material. The ternary material may include, for example, SiON, AlON, SiOC, or TeSeOₓ. For example, the target material may include a quaternary material. The quaternary material may include, for example, (Ti, Al)N, (Zr, Ti)N, or LaAlO₃. When the target material includes two or more constituent elements, two or more precursors respectively including the constituent elements are necessary, and the purging process may be performed on each of the two or more precursors.

In the present embodiment, for example, an example of a method of forming an amorphous layer of boron nitride that is a binary material is described. When the internal temperature of the reaction chamber 2 reaches a certain process temperature, a process of depositing a boron nitride layer on the deposition surface 11 is performed by exposing the deposition surface 11 to the precursor of the target material, for example, precursors of boron nitride.

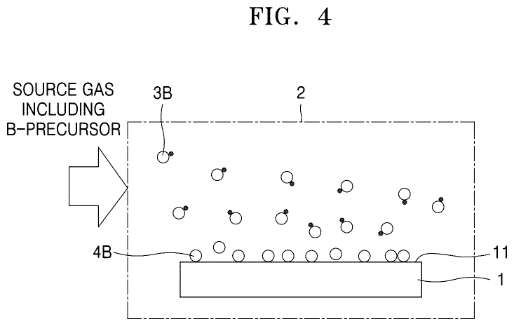

First, as illustrated in FIG. 4, under the first process pressure, the deposition surface 11 is exposed to a boron-precursor 3B. For example, the boron-precursor 3B may include BBr₃, BCl₃, BH₃, BF₃, B2H₆, (CH₃)₃B, or TEB(Triethylborane, (CH₃CH₂)₃B). The first process pressure may be, for example, 100 mTorr to 200 mTorr. An exposure time may be 1 second to 30 seconds. For example, the exposure time may be 3 seconds to 30 seconds. The boron-precursor 3B may be supplied to the reaction chamber 2 together with a carrier gas, for example, an inert gas. A mixture ratio of a mixed gas (source gas) of the boron-precursor 3B and the carrier gas may be variously changed according to the growth conditions of the amorphous layer of boron nitride. The mixture ratio may be, for example, 1:10 to 1:5000. The mixture ratio may be controlled by controlling a flow rate of the boron-precursor 3B and the carrier gas supplied to the inside of the reaction chamber 2.

For example, a mixed gas including TEB as the boron-precursor 3B is supplied to the inside of the reaction chamber 2 and the deposition surface 11 is exposed to the TEB for about 5 seconds. Then, in the reaction chamber 2 at a high temperature, for example, 200~600° C., boron atoms in the boron-precursor 3B may be activated and adsorbed on the deposition surface 11 by a self-limiting surface reaction. Accordingly, a boron atomic layer 4B may be formed on the deposition surface 11. The boron atomic layer 4B may be a layer mainly including boron atoms. The boron atomic layer 4B may be a layer in which boron atoms and the boron-precursor 3B are mixed.

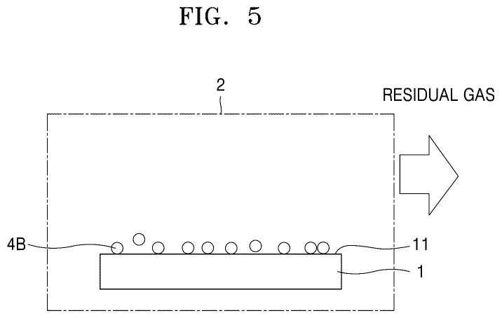

Next, as illustrated in FIG. 5, a purging process (first purging process) of removing a residual gas in the reaction chamber 2 by using an inert gas is performed. The residual gas may include, for example, the boron-precursor 3B not adhering to the deposition surface 11, reactants of the boron-precursor 3B, and a carrier gas. The inert gas may include, for example, at least one of argon gas, neon gas, nitrogen gas, helium gas, krypton gas, and xenon gas. The process pressure of the first purging process may be, for example, 100 mTorr to 300 mTorr. The process time of the first purging process may be, for example, 1 second to 30 seconds. In the present embodiment, an argon gas is used as a purging gas, and the process time may be about 10 seconds.

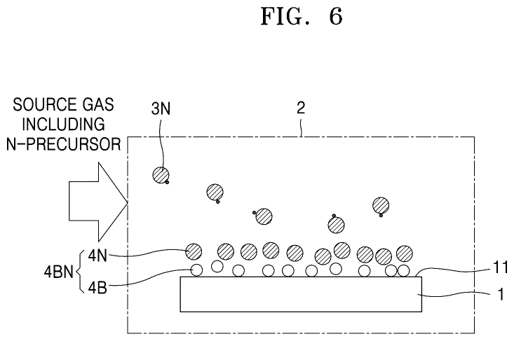

Next, as illustrated in FIG. 6, under the first process pressure, the deposition surface 11 is exposed to a reaction gas, for example, a nitrogen-precursor 3N. For example, the nitrogen-precursor 3N may include NH₃ or N₂, or a combination of each of NH₃ or N₂ and H₂. In the process of exposing the nitrogen-precursor 3N, the first process pressure may be, for example, 100 mTorr to 500 mTorr. The exposure time may be 1 second to 30 seconds, for example, 3 seconds to 30 seconds. The nitrogen-precursor 3N may be supplied to the reaction chamber 2 together with the carrier gas, for example, the inert gas. A mixture ratio of a mixed gas (reaction gas) of the nitrogen-precursor 3N and the carrier gas may be variously changed according to the growth conditions of the amorphous layer of boron nitride. The mixture ratio may be, for example, 1:10 to 1:5000. The mixture ratio may be controlled by controlling a flow rate of the nitrogen-precursor 3N and the carrier gas supplied to the inside of the reaction chamber 2.

For example, a mixed gas including NH₃ is supplied to the inside of the reaction chamber 2 and the deposition surface 11 is exposed to NH₃ for about 30 seconds. Then, in the reaction chamber 2 at a high temperature, nitrogen atoms in the nitrogen-precursor 3N are activated so that boron and nitrogen react each other. As illustrated in FIG. 6, a boron nitride layer 4BN in a solid state may be formed. As the process temperature is 250° C. to 400° C., the boron nitride layer 4BN that is formed is amorphous. In FIG. 6, although the boron atomic layer 4B and a nitrogen atomic layer 4N are separately indicated, this is an example, and the boron nitride layer 4BN is substantially formed on the deposition surface 11.

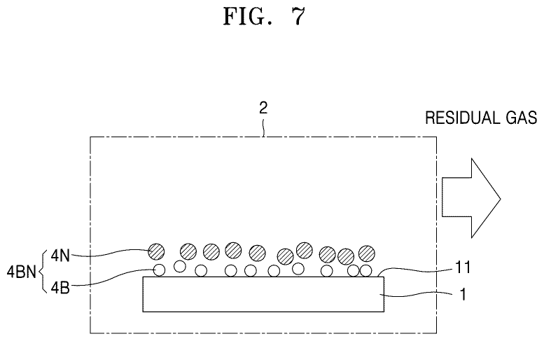

Next, as illustrated in FIG. 7, a purging process (second purging process) of removing a residual gas in the reaction chamber 2 by using an inert gas is performed. The residual gas may include, for example, the nitrogen-precursor 3N not adhering to the deposition surface 11, extra by-products generated in a process of forming the boron nitride layer 4BN, and the carrier gas. The inert gas may include, for example, at least one of argon gas, neon gas, nitrogen gas, helium gas, krypton gas, and xenon gas. The process pressure of the second purging process may be, for example, 100 mTorr to 300 mTorr. The process time of the second purging process may be, for example, 1 second to 30 seconds. In the present embodiment, an argon gas is used as a purging gas, and the process time is about 5 seconds.

Next, under a second process pressure, an operation of plasma-treating the thin film of the target material, for example, the boron nitride layer 4BN, is performed (S30). A plasma device (not shown) for generating plasma in the reaction chamber 2 is not particularly limited. For example, the plasma device may be a device for providing plasma including inductively coupled plasma, microwave plasma, capacitively coupled discharge plasma, electron cyclotron resonance plasma, or helicon plasma. When an electric field is induced by the plasma device inside the reaction chamber 2, plasma may be generated by the induced electric field. When the kinetic energy of plasma ions is higher than 35 eV, the thin film of the target material may be crystallized. When the kinetic energy of plasma ions is much higher, the thin film of the target material is etched by plasma ions with high energy so that uniformity of the thin film may deteriorate. Considering the above, the kinetic energy of plasma ions may be 35 eV or less. Plasma power may be set and adjusted such that the kinetic energy of plasma ions is 35 eV or less. The second process pressure may be, for example, 100 mTorr to 500 mTorr. A plasma treatment time may be 1 second to 60 seconds. For example, the plasma treatment time may be 5 seconds to 60 seconds. The thin film of the target material formed on the deposition surface 11 may be maintained in an amorphous state by the plasma treatment process so that density may be improved. The plasma treatment process may be referred to as, for example, a soft radical treatment (SRT) process.

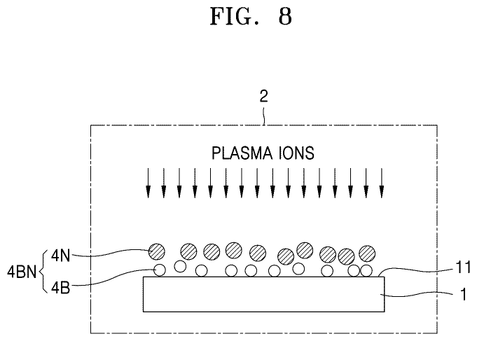

In an embodiment, as illustrated in FIG. 8, in a state in which the kinetic energy of plasma ions is 35 eV or less, the boron nitride layer 4BN may be plasma-treated for 1 second to 60 seconds, for example, for about 10 seconds. Accordingly, while the boron nitride layer 4BN is maintained in the amorphous state, the density of the boron nitride layer 4BN may be improved.

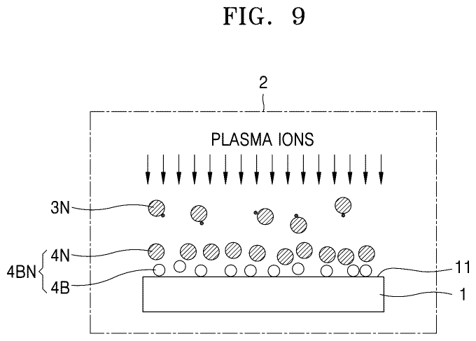

Referring to FIG. 9, in a plasma treatment process, at least one of precursors of the target material may be supplied to the reaction chamber 2. Accordingly, the quality of the target material thin film may be improved by providing deficiency elements to the thin film of the target material.

For example, in the plasma treatment process of the boron nitride layer 4BN, at least one of the boron-precursor 3B and the nitrogen-precursor 3N may be supplied to the reaction chamber 2. In an embodiment, NH₃ may be supplied, as the nitrogen-precursor 3N, to the reaction chamber 2. Although not illustrated, NH₃ and H₂ may be supplied together. Accordingly, the quality of the boron nitride layer 4BN may be improved by supplementing the nitrogen deficiency of the boron nitride layer 4BN.

Next, after the plasma-treating, the maintaining process S40 is performed under a third process pressure lower than the second process pressure for a certain maintaining time. After undergoing the plasma treatment process, high energy radicals and/or ions may remain inside the reaction chamber 2. In this state, when the subsequent process, for example, the deposition process S20 described above is performed immediately, the constituent elements of the target material provided on the deposition surface 11 by the precursors may be crystallized by high energy radicals and/or ions. Taking this into account, after turning off the plasma device and before performing the deposition process S20 again, the pressure inside the reaction chamber 2 is reduced from the second process pressure to the third process pressure and maintained for a certain maintaining time. The maintaining time may be 1 second to 60 seconds, for example, 5 seconds to 60 seconds. During the maintaining time, the energy level of the residual radicals and/or ions inside the reaction chamber 2 may be lowered, and crystallization of the constituent elements in the subsequent deposition process S20 may be reduced or prevented. The third process pressure may be, for example, 1 mTorr to 100 mTorr. In an embodiment, in the maintaining process, the inside of the reaction chamber 2 may be maintained close to vacuum. In an embodiment, in the maintaining process, an inert gas may be supplied to the inside of the reaction chamber 2.

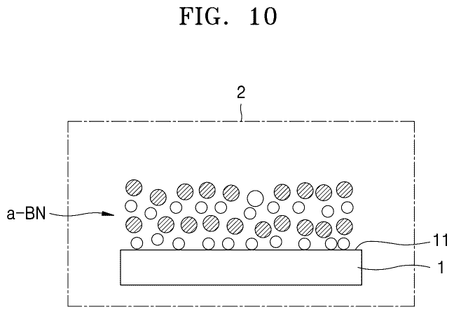

Next, the deposition process S20, the plasma treatment process S30, the maintaining process S40 are sequentially repeated ‘n1’ times (S50). Accordingly, as illustrated in FIG. 10, an amorphous material layer of a target material, for example, amorphous layer of boron nitride (a-BN) may be formed on the deposition surface 11. The number of repetitions “n1” may be determined considering a target thickness of the amorphous material layer of the target material, for example, the amorphous layer of boron nitride.

As such, the density of the amorphous material layer may be improved while maintaining the amorphous properties by the ISCP. Furthermore, before performing the subsequent deposition process after the plasma-treating process, as the maintaining process is performed in a plasma off state for a certain maintaining time, the crystallization of the subsequent precursor by the radicals and/or ions may be prevented.

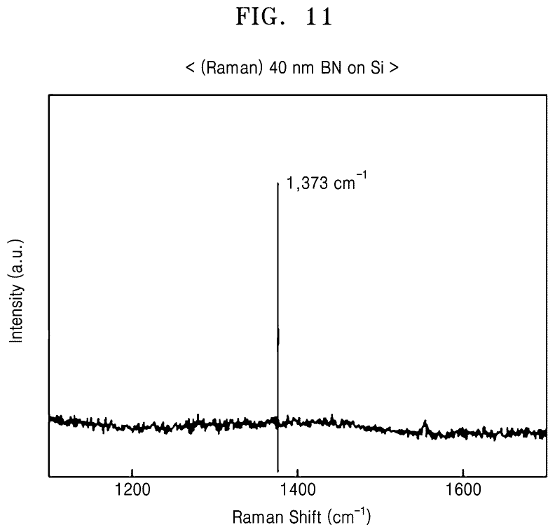

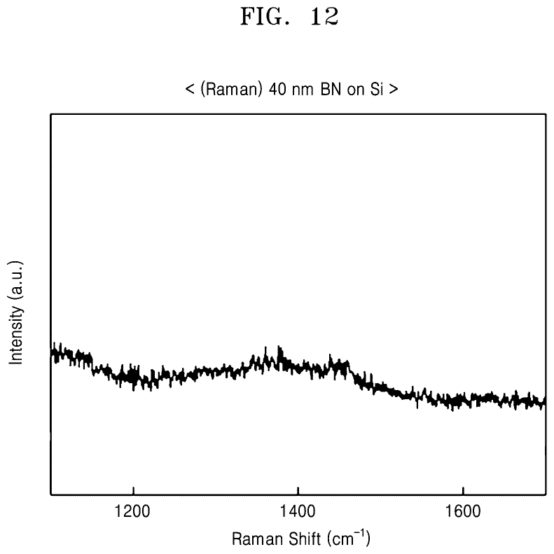

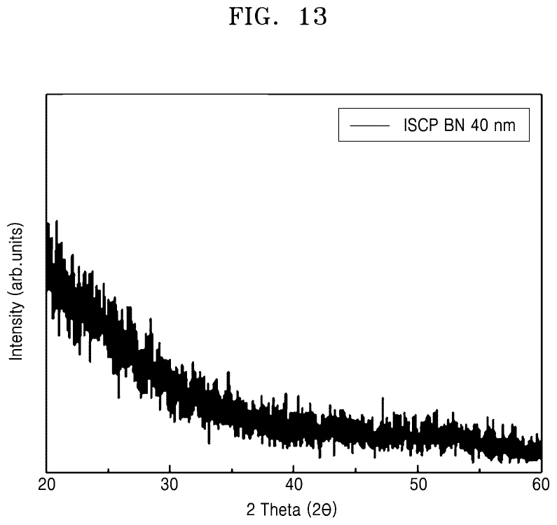

FIG. 11 is a graph showing a Raman spectrum of a boron nitride layer formed by a T-ALD process. FIG. 12 is a graph showing a Raman spectrum of a boron nitride layer formed by the method using the ISCP according to the present embodiment. Referring to FIG. 11, in the case of a boron nitride layer formed by the T-ALD process, an absorption peak exists in a wavelength band of 1373 cm⁻¹, which means that the boron nitride layer formed by the T-ALD process is a crystalline thin film. Referring to FIG. 12, in the case of a boron nitride layer formed by the method according to the present embodiment, an absorption peak does not exist in a wavelength band of 1300 cm⁻¹ to 1400 cm⁻¹, which means that the boron nitride layer formed by the method according to the present embodiment is an amorphous material layer. Such a result may be confirmed from FIG. 13 showing an X-ray diffraction spectrum of a boron nitride layer formed by the method according to the present embodiment.

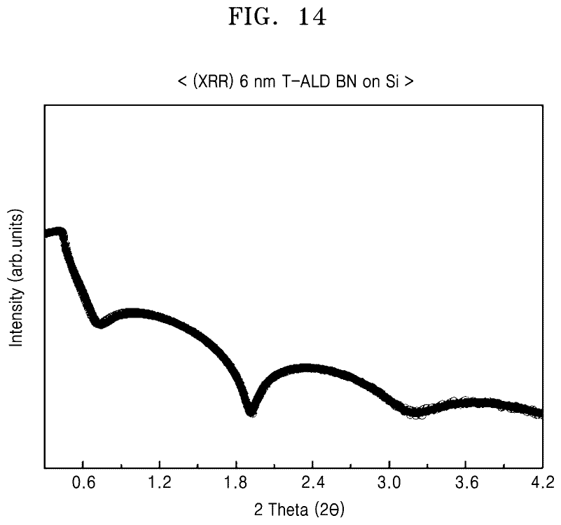

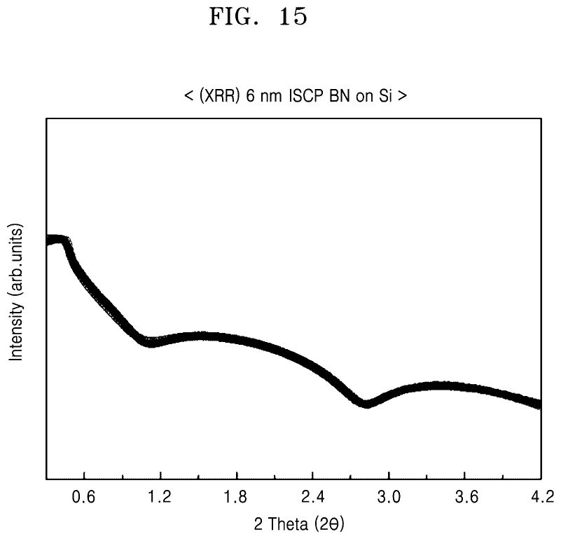

FIG. 14 is a graph showing an X-ray reflection spectrum of a boron nitride layer formed by the T-ALD process. FIG. 15 is a graph showing an X-ray reflection spectrum of a boron nitride layer formed by the method using the ISCP according to the present embodiment. Referring to FIGS. 14 and 15, it may be seen that the boron nitride layer formed by the method according to the present embodiment exhibits higher density than the boron nitride layer formed by the T-ALD process.

According to calculations, the density of the boron nitride layer formed by the T-ALD process is about 1.65 g/cm³, and the density of the boron nitride layer formed by the method according to the present embodiment is about 2.16 g/cm³. Accordingly, according to the method using the ISCP according to the present embodiment, an amorphous layer of boron nitride having a density of about 1.7 g/cm³ or more, for example, 1.7 g/cm³ to 3.45 g/cm³, may be formed. Furthermore, it may be seen through X-ray photoelectron spectroscopy (XPS) that B:N stoichiometry is 1:1.04. The amount of residual carbon is confirmed to be about 1.2 at %, and a very high quality amorphous layer of boron nitride may be realized by the formation method of the present embodiment.

Furthermore, according to the formation method of the present embodiment, formation of an amorphous layer of boron nitride with a dielectric constant of 4 or less is possible. In order to measure the dielectric constant of an amorphous layer of boron nitride, the amorphous layer of boron nitride is formed on a overdoped Si substrate according to the formation method of the present embodiment, and an upper electrode, for example, a ruthenium (Ru) electrode, is formed on the amorphous layer of boron nitride so that a capacitor having a metal-insulator-metal (MIM) structure may be formed. After measuring capacitor-voltage-sweep (CVS), the dielectric constant of the amorphous layer of boron nitride may be calculated using the thickness of the amorphous layer of boron nitride and the area of the upper electrode. The amorphous layer of boron nitride is grown at a growth temperature of 400° C. using BBr₃ and NH₃ as a boron source and a nitrogen source, respectively. In this case, the dielectric constant of the amorphous layer of boron nitride is 2.11±0.92, which confirms that a dielectric constant of the amorphous layer of boron nitride is 4 or less.

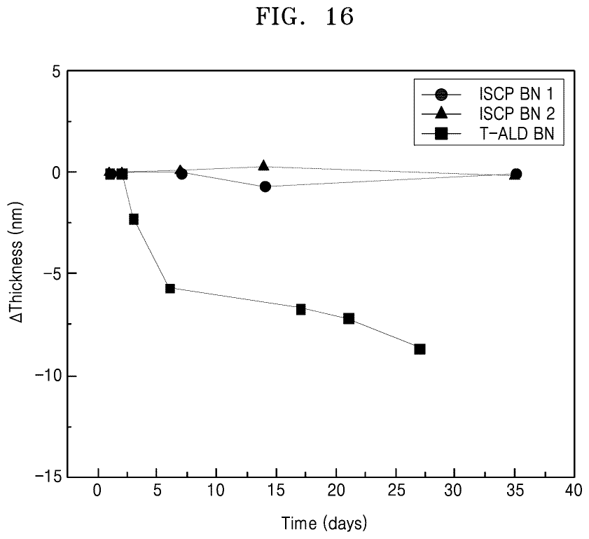

When the boron nitride layer is exposed to the air, moisture and/or oxygen in the air and boron in the boron nitride layer may react, causing the reactant to volatilize. Higher density boron nitride layers may have higher air stability. FIG. 16 is a graph showing an air stability test result of the boron nitride layer formed by the T-ALD process and the boron nitride layer formed by the method using the ISCP according to the present embodiment. Referring to FIG. 16, the boron nitride layer formed by the method according to the present embodiment shows higher air stability due to almost no change in thickness in the air.

As a method to check the air stability, a boron-oxygen bonding (B—O bonding) content in the boron nitride layer may be measured after leaving the boron nitride layer in the air for a long time, for example, a month or more. According to a measurement result, the B—O bonding content of a boron nitride layer formed by PE-ALD is about 1 at %, and the B—O bonding content of the boron nitride layer formed by T-ALD is about 6.8 at %, whereas the B—O bonding content of the boron nitride layer formed by the method according to the present embodiment is about 0.1 at % or less, showing very high air stability.

The boron nitride layer formed by the method according to the present embodiment shows high step coverage. In the case of PE-ALD according to the related art, a thin film of boron nitride is formed by providing plasma while supplying a source gas and a reaction gas to a reaction chamber. In this case, as described above, due to collisions of radicals and/or ions of plasma, it may be difficult to obtain high step coverage, for example, 90% or more, because the constituent elements do not reach deep into the trench of the deposition surface with a high aspect ratio. According to the formation method of the present embodiment, as plasma is not provided in the deposition process S20, the collisions of radicals and/or ions as in the PE-ALD do not occur so that high step coverage may be implemented. Experimentally, according to the present embodiment, the formation of boron nitride layers with a step coverage of about 90% or more is possible, which may be confirmed by imaging the grown amorphous layer of boron nitride using transmission electron microscopy (TEM).

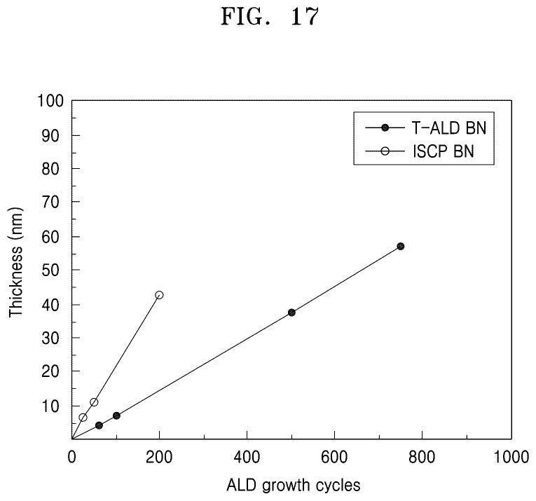

According to the formation method of the present embodiment, faster thin film growth is possible. In the case of T-ALD in the growth of boron nitride layers, a growth rate per cycle (GPC) is about 0.6 Å/cycle, but in the case of the formation method of the present embodiment where ISCP is applied, the GPC is about 2.13 Å/cycle, which enables thin film growth that is about 3 times or more faster. This may be confirmed from the graph of FIG. 17, which measures the thickness of the boron nitride layer formed by T-ALD and the formation method according to the present embodiment.

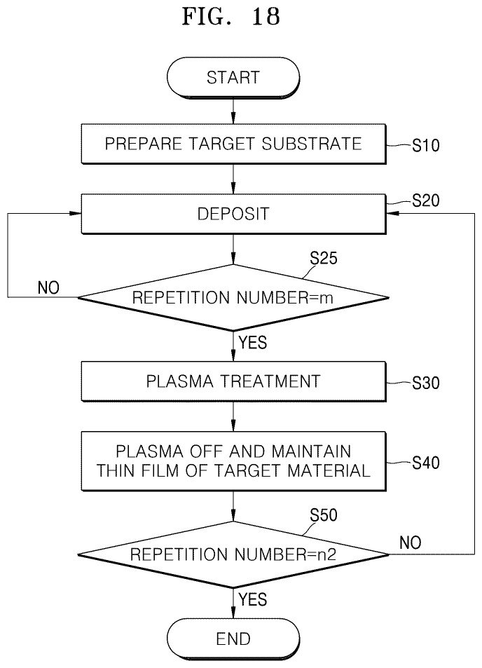

FIG. 18 is a flowchart of a method of forming an amorphous material layer, according to an embodiment. The method of forming an amorphous material layer, according to the present embodiment, differs from the method of forming an amorphous material layer described with reference to FIG. 1 in that the deposition process S20 is repeated multiple times, for example, m times (S25), and then the plasma treatment process S30 and the maintaining process S40 are performed. Accordingly, substantially the same process is indicated by the same reference numeral, and redundant explanations are omitted.

The number of repetitions ‘m’ of the deposition process S20 is two times or more and is not particularly limited. By repeating, for example, ‘n2’ times, the deposition process S20 multiple times, the plasma treatment process S30, and the maintaining process S40, the amorphous material layer of the target material may be formed on the deposition surface 11. The number of repetitions ‘n2’ in the operation S50 may be determined considering a target thickness of an amorphous material layer of a target material, for example, an amorphous layer of boron nitride.

A case of forming an amorphous layer of boron nitride is described with respect to the method of forming an amorphous material layer according to the embodiments of the disclosure, but the method of forming an amorphous material layer, according to the disclosure may be applied to formation of various amorphous material layers of a target material including one or more constituent elements. The target material may include various low-k or ultra-low-k materials. For example, the target material may include a unary material such as C, Si, or B, a binary material such as SiN, BN, Al₂O₃, HfO₂, SiO₂, ZrO₂, SiC, ZnTe, GeTe, or SiTe, a ternary material such as SiON, AlON, SiOC, or TeSeOₓ, or a quaternary material such as (Ti, Al)N, (Zr, Ti)N, or LaAlO₃.

The low-k material or ultra-low-k material formed by the formation method according to the disclosure may be used as an interlayer insulating layer, a spacer, or a device isolation layer in various semiconductor device such as an image sensor, an electric field effect transistor, and a memory device, and in integrated circuits of various electronic devices employing the same.

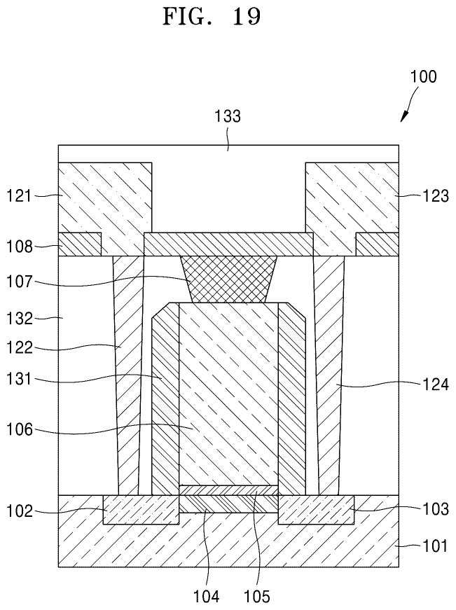

FIG. 19 is a diagram showing an electronic device including an electric field effect transistor 100, according to an embodiment. Referring to FIG. 19, the electric field effect transistor 100 may include a substrate 101 in which a source region 102, a drain region 103, and a channel region 104 between the source region 102 and the drain region 103 are provided. A gate insulating layer 105 including a high-k material is disposed on the channel region 104, and a gate electrode 106 is disposed on the gate insulating layer 105. Reference numeral 107 denotes a gate contact for applying a voltage to the gate electrode 106. An inter-metallic dielectric layer 132 is disposed on the substrate 101. The gate insulating layer 105, the gate electrode 106, and the gate contact 107 are embedded in the inter-metallic dielectric layer 132. A capping layer 108 is disposed on the inter-metallic dielectric layer 132. A source electrode 121 and a drain electrode 123 are electrically connected to the source region 102 and the drain region 103, respectively, through conductor plugs 122 and 124 penetrating the capping layer 108 and the inter-metallic dielectric layer 132. An interlayer insulating layer 133 is disposed on the capping layer 108. The source electrode 121 and the drain electrode 123 are embedded in the interlayer insulating layer 133.

An isolation layer 131 for reducing or preventing parasitic capacitance between the gate electrode 106 and other metal wires adjacent thereto is arranged on a side of the gate electrode 106. In order to reduce the parasitic capacitance, the isolation layer 131 may be formed of a material with an ultra-low k of 4 or less, and the amorphous layer of boron nitride formed by a method of the disclosure may be adopted as the isolation layer 131. Furthermore, the inter-metallic dielectric layer 132 and the interlayer insulating layer 133 may each include a low-k material. Accordingly, as the inter-metallic dielectric layer 132 and the interlayer insulating layer 133, various dielectric amorphous material layers formed by the method of the disclosure may be adopted.

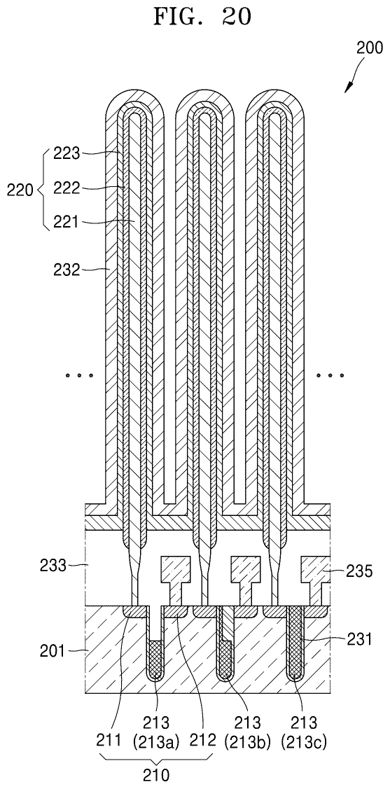

FIG. 20 is a diagram showing a memory device 200 according to an embodiment. The memory device 200 of the present embodiment includes 1C-1T type dynamic random access memory (DRAM) adopting a so-called buried channel array transistor (BCAT). Referring to FIG. 20, the memory device 200 may include a transistor 210 and a capacitor 220. The transistor 210 may include a source region 211, a drain region 212, a channel region, and a gate electrode 213. The source region 211 and the drain region 212 are provided in a substrate 201. The gate electrode 213 extends between the source region 211 and the drain region 212 toward the inside of the substrate 201. For example, the gate electrode 213, as indicated by reference numeral 213a, may have a shape of being buried in the substrate 201 and filled with a dielectric material thereabove. For example, the gate electrode 213, as indicated by reference numeral 213b, may have a shape of being buried in the substrate 201 and partially extending to an upper surface of the substrate 201. For example, the gate electrode 213, as indicated by reference numeral 213c, may have a shape of entirely extending from the inside of the substrate 201 to the upper surface of the substrate 201. The channel region extends from the source region 211 to the drain region 212 along the outer edge of the gate electrode 213. An insulating layer 231 is provided between the gate electrode 213 and the source region 211, the drain region 212, and channel region. Accordingly, the channel region extends from the source region 211 to the drain region 212 along the outer edge of the insulating layer 231. The drain region 212 is connected to a bit line. The gate electrode 213 is connected to a word line. An inter-metallic dielectric layer 233 is provided on the upper surface of the substrate 201. The capacitor 220 is disposed on the inter-metallic dielectric layer 233. The capacitor 220 may include a first metal layer 221, a second metal layer 223, and a dielectric layer 222 between the first metal layer 221 and the second metal layer 223. The first metal layer 221 is electrically connected to the source region 211 via the inter-metallic dielectric layer 233. The transistor 210 and the capacitor 220 have a one-to-one correspondence. A drain contact 235 may be connected to the drain region 212.

In order to reduce and prevent parasitic capacitance caused by the gate electrode 213 and the source region 211, the channel region, and the drain region 212, which are adjacent to the gate electrode 213, the insulating layer 231 may be formed of a material with an ultra-low k of 4 or less, and the amorphous layer of boron nitride formed by the formation method of the disclosure may be adopted as the insulating layer 231. In order to reduce or prevent parasitic capacitance between two adjacent capacitors 220, the capacitor 220 may be coated with an isolation layer 232 with an ultra-low k of 4 or less, and the amorphous layer of boron nitride formed by the formation method of the disclosure may be adopted as the isolation layer 232. Furthermore, the inter-metallic dielectric layer 233 may include a low-k material. Accordingly, various dielectric amorphous material layers formed by the formation method of the disclosure the disclosure may be adopted as the inter-metallic dielectric layer 233.

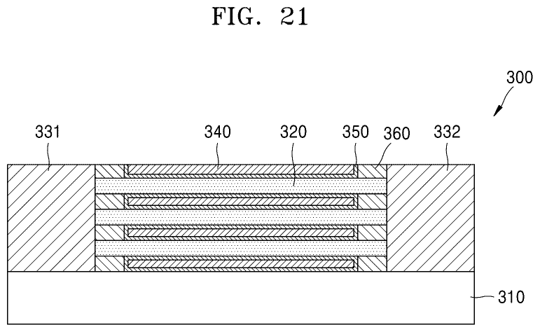

FIG. 21 is a schematic cross-sectional view of an electric field effect transistor 300 according to an embodiment. The electric field effect transistor 300 illustrated in FIG. 21 is an electric field effect transistor of a so-called gate all around type. The electric field effect transistor 300 may be applied to, for example, a logic device or a memory device.

Referring to FIG. 21, the electric field effect transistor 300 may include a substrate 310, a source 331 and a drain 332 arranged on the substrate 310, a plurality of channels 320 arranged between the source 331 and the drain 332 and spaced apart from each other in a direction perpendicular to the substrate 310, and a plurality of gates 340 opposite to the plurality of channels 320. Both ends of each of the plurality of channels 320 may be in contact with a source 331 and a drain 332. A gate insulating layer 350 is provided between a gate 340 and a channel 320. The gate insulating layer 350 may surround at least a part of the gate 340. For example, the gate 340 and the channel 320 may be alternately arranged in a direction perpendicular to the substrate 310, and the gate insulating layer 350 may surround the gate 340. The gate insulating layer 350 may include a dielectric material having a relatively high dielectric constant. The gate insulating layer 350 may insulate between the channel 320 and the gate 340 and restrict a leakage current. The plurality of gates 340 are spaced apart from the source 331 and the drain 332. A spacer 360 is provided between the plurality of gates 340 and the source 331 and the drain 332.

As the source 331, the plurality of gates 340, and the drain 332 are arranged on the substrate 310 in a horizontal direction to face one another, parasitic capacitance may be generated between the source 331 and the gate 340 and between the gate 340 and the drain 332. In order to reduce the parasitic capacitance, the spacer 360 may include the amorphous layer of boron nitride formed by the formation method of the disclosure. As the amorphous layer of boron nitride has an ultra-low-k of 4 or less, the parasitic capacitance may be effectively reduced or prevented.

According to some example embodiments, an amorphous material layer (e.g., an amorphous boron nitride layer) may be formed.

According to some example embodiments, a low-k amorphous material layer (e.g., a low-k amorphous boron nitride layer) and/or an ultra-low-k amorphous material layer (e.g., an ultra-low-k amorphous boron nitride layer) may be formed.

According to some example embodiments an amorphous material layer (e.g., an amorphous boron nitride layer) having higher step coverage may be realized.

According to some example embodiments an amorphous material layer (e.g., an amorphous boron nitride layer) having higher air stability may be formed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of forming an amorphous layer of boron nitride, the method comprising:
placing a target substrate having a deposition surface in a reaction chamber;
depositing a boron nitride layer on the target substrate by sequentially exposing the deposition surface to a boron-precursor and a nitrogen-precursor;
plasma-treating the boron nitride layer;
maintaining the boron nitride layer at a process pressure lower than a process pressure during the plasma-treating for a certain maintaining time after the plasma-treating; and
repeating multiple times the depositing the boron nitride layer, the plasma-treating the boron nitride layer, and the maintaining the boron nitride layer.

2. The method of claim 1, wherein in the depositing of the boron nitride layer, a process temperature ranges from 250° C. to 400° C.

3. The method of claim 1, wherein, in the depositing of the boron nitride layer,
a process pressure of a process for supplying the boron-precursor ranges from 100 mTorr to 200 mTorr, and
a process pressure of a process for supplying the nitrogen-precursor ranges from 100 mTorr to 500 mTorr.

4. The method of claim 1, wherein in the plasma-treating of the boron nitride layer, a kinetic energy of ions is 35 eV or less.

5. The method of claim 1, wherein in the plasma-treating of the boron nitride layer, a process pressure ranges from 100 mTorr to 500 mTorr.

6. The method of claim 1, wherein in the plasma-treating of the boron nitride layer, at least one of the boron-precursor and the nitrogen-precursor is supplied to the reaction chamber.

7. The method of claim 1, wherein the process pressure in the maintaining of the boron nitride layer ranges from 1 mTorr to 100 mTorr.

8. The method of claim 1, wherein the certain maintaining time ranges from 1 second to 60 seconds.

9. The method of claim 1, wherein the depositing of the boron nitride layer is performed multiple times, followed by the plasma-treating of the boron nitride layer and the maintaining of the boron nitride layer.

10. The method of claim 1, wherein a density of the amorphous layer of boron nitride ranges from 1.7 g/cm³ to 3.45 g/cm³.

11. The method of claim 1, wherein a dielectric constant of the amorphous layer of boron nitride is 4 or less.

12. A method of forming an amorphous material layer, the method comprising:
placing a target substrate having a deposition surface in a reaction chamber;
depositing a thin film of a target material on the deposition surface by exposing the deposition surface to a precursor of the target material;
plasma-treating the thin film of the target material;
maintaining the thin film of the target material at a process pressure lower than a process pressure during the plasma-treating for a certain maintaining time after the plasma-treating; and
repeating multiple times the depositing of the thin film of the target material, the plasma-treating of the thin film of the target material, and the maintaining of the thin film of the target material.

13. The method of claim 12, wherein in the depositing of the thin film of the target material, a process temperature ranges from 250° C. to 400° C.

14. The method of claim 12, wherein in the plasma-treating of the thin film of the target material, a kinetic energy of ions is 35 eV or less.

15. The method of claim 12, wherein in the plasma-treating of the thin film of the target material, at least one of precursors of the target material is supplied to the reaction chamber.

16. The method of claim 12, wherein the process pressure in the maintaining of the thin film of the target material ranges from 1 mTorr to 100 mTorr.

17. The method of claim 16, wherein the certain maintaining time ranges from 1 second to 60 seconds.

18. The method of claim 12, wherein the depositing of the thin film of the target material is performed multiple times, followed by the plasma-treating of the thin film of the target material and the maintaining of the thin film of the target material.

19. The method of claim 12, wherein the target material comprises C, Si, B, SiN, BN, Al₂O₃, HfO₂, SiO₂, ZrO₂, SiC, ZnTe, GeTe, SiTe, SiON, AlON, SiOC, TeSeOₓ, (Ti, Al)N, (Zr, Ti)N, or LaAlO₃.

20. The method of claim 12, wherein the target material includes a unitary material, a binary material, or a ternary material.
